(19) United States
(12) Patent Application Publication
(10) Pub. No.: US 2003/0114125 A1
(43) Pub. Date: Jun. 19, 2003

(54) Interference suppression in a radio receiver

(76) Inventors: Essam Sourour, San Diego, CA (US); Anders Ericsson, Sandby (SE)

Correspondence Address: Ronald L. Grudziecki, BURNS, DOANE, SWECKER & MATHIS, L.L.P., P.O. Box 1404, Alexandria, VA, 22313-1404, US

(21) Appl. No.: 10/017,745

(22) Filed: Dec. 14, 2001

(51) Int. Cl. H03D 1/04

(52) U.S. Cl. 455/133; 375/346

(57) ABSTRACT

A method and apparatus for reducing interpath interference between a first signal and at least one other signal is provided. The invention provides for obtaining a relative phase of the first signal and the at least one other signal, determining an interference component on the first signal caused by the at least one other signal, and removing the interference component from the first signal. The invention is particularly adapted for non-coherent mean-value calculations in a RAKE receiver.

### BACKGROUND

This invention generally relates to communication techniques in multipath communication systems. More particularly, the present invention provides a method that improves the ability of a multipath receiver to separate signals having a small difference in delay.

Spread spectrum communication technology has been used in military communications since the days of World War II, primarily for two purposes: to overcome the effects of strong intentional interference on a certain frequency band and to protect the signal from unauthorized access. Both of these goals can be achieved by “spreading” the signal spectrum to make it virtually indistinguishable from background noise, hence the term “spread spectrum modulation.”

Code Division Multiple Access, or CDMA, is a digital cellular spread spectrum multiple access method. In known CDMA systems, a number of base stations are typically located within a service area. Each base station uses one or more CDMA channels to communicate with one or more mobile stations located within the same service area. The base-to-mobile station transmission direction is known as the “forward link” or downlink, and the mobile-to-base station direction is known as the “reverse link” or uplink.

In a CDMA system, an information data stream to be transmitted is modulated by a data sequence with a much higher data rate, referred to as a “signature sequence.” Each element of the signature sequence typically represents one binary logical symbol (“0” or “1”). The signature sequence usually comprises N bits, wherein each of the N bits is denoted as a “chip.” One way to generate such a signature sequence is by using a periodic binary sequence of pseudorandom signals to modulate a periodic impulse stream of period T_{c}, also referred to as the “chip duration.” The sequence of pseudorandom signals is also known as a pseudo noise (PN) sequence, so called because it appears random but can be replicated by an authorized receiver.

The information data stream and the high bit rate signature sequence are combined by first mapping the binary logical signals (“0” or “1”) to real values (“+1” or “−1”) and multiplying the two bit streams together. The combination of the lower bit rate information data stream with the higher bit rate signature sequence creates a noiselike wideband signal. This technique is called “coding” or “spreading” the information data stream and is well known in the art.

In traditional cellular communication systems, co-channel interference between channels due to spectrum reuse is one of the main limiting factors in achieving a high system capacity. One of the most notable features of CDMA technology is universal frequency reuse, which means that all users within a CDMA system occupy a common frequency spectrum allocation. This is accomplished by allocating different codes to different channels. On the downlink, each base station transmits a unique, unmodulated spreading code, called either a “pilot code,” a “pilot channel,” or simply a “pilot.” The pilot generally consists of a sequence of chips, each having a chip duration T_{c}. Each pilot is a different shift of a common complex sequence. Hence, on the forward link, each base station transmits a unique, unmodulated pilot channel, and may additionally transmit a synchronization channel, paging channels, and traffic channels. The term “CDMA channel set” is used to refer to a set of channels transmitted by a base station.

Each mobile station in a CDMA system searches for pilot codes to detect the presence of base station signals and to measure their strengths. For purposes of this disclosure, a forward CDMA channel set containing one or more traffic channels assigned to the mobile station is referred to as an “active channel,” and the pilot signal of such an active channel is referred to as an “active pilot.” Conversely, a CDMA channel set which contains no traffic channels assigned to the mobile station is referred to as a “non-active channel,” and the pilot signal of such a non-active channel is referred to as a “non-active pilot.” Since no traffic information is transmitted from the base station to the mobile station on the non-active channels, there is no need for demodulating these channels. Thus, the mobile station must only be able to demodulate the active CDMA channel sets.

A well-known source of degradation common to all known wireless multiple access systems, particularly in terrestrial environments, is known as “multipath fading.” In a multipath environment, the transmitted signal follows several propagation paths from a transmitter to a receiver, typically as a result of the signal reflecting off one or more objects before arriving at the receiver. Since the various propagation paths of the transmitted signal are of unequal lengths, several copies of the transmitted signal, referred to as “rays,” will arrive at the receiver with varying time delays. In a multipath fading channel, phase interference between different rays may cause severe fading and result in signal dropout or cancellation.

A mobile station in a CDMA system is typically equipped with a receiver for demodulating active channels and compensating for multipath delays. A block diagram of a typical CDMA receiver is shown in FIG. 7. The receiver is generally referred to as a RAKE receiver, since it “rakes” all the multipath contributions together. A RAKE receiver consists of a number of processing units, or RAKE “fingers”, and a combiner, which combines the output from the each of the RAKE fingers. When demodulating a multipath fading channel, each finger of the RAKE receiver must be synchronized with one of the diverse propagation paths of the channel. A RAKE receiver comprising L fingers is able to detect, at most, L copies of the transmitted signal, which are individually despread by the RAKE fingers according to the individual delays and added coherently in the combiner. At the addition performed by the combiner, each despread output from a RAKE finger is multiplied with a complex weight. Typically, these weights can be set as the complex conjugate to the channel impulse response at the appropriate delays. For this, the channel impulse response must be estimated at the delays, a process which, for example, can be made by a separate algorithm in the DSP. The resulting signal will thus comprise a collection of all the time delayed copies of the transmitted signal.

As previously described, due to multipath propagation, the transmitted signals will arrive at different times at the mobile station and result in a number of time delayed copies of the transmitted signal at the receiver. The relative time delays of the received rays must be determined in order to synchronize the various rays with the corresponding fingers of the RAKE receiver. Unfortunately, the number and magnitude of the time delays may change due to movement of the mobile station, i.e., variable distance and velocity relative to the transmitting base station for users in motion. Also, movement of the mobile station may cause new channel paths to appear and old channel paths to disappear. Hence, the mobile station must continuously monitor the signals received along all propagation paths of an active channel in order to search for new, stronger channel paths. To perform this monitoring efficiently, the multipath time delays must be substantially continually measured or estimated in a fast and accurate manner. Typically, this is performed by a channel delay estimator.

The simplest approach to delay estimation (DE) is evaluating the impulse response of the channel over the whole range of the possible delays, or the delay spread, of the channel. The resulting complex delay profile (CDP) or power delay profile (PDP) may then be subjected to peak detection, and the peak locations are reported to the RAKE as the delay estimates. However, the processing and power consumption expense of frequently executing this path searching routine is usually prohibitive. Therefore, typical implementations use shortened search windows, reduced searcher resolution, and additional short sub-searchers to produce higher-resolution estimates of certain areas of the PDP.

A typical approach in the case where several distinct multipath channels with different path structure need to be characterized includes applying a delay estimation and subsequent channel estimation algorithm to each of these channels.

For reference, we review a typical delay estimation (DE) approach, shown in FIG. 1. Since the realization of the DE functionality depends on the specific system parameters and hardware resources, a universally applicable solution cannot be presented. Still, while there exist a number of basic architectures for DE, and even more numerous detailed variations thereof, a fairly advanced practical implementation can be said to include of the following stages:

Path searcher (PS) 101—a device that computes instantaneous impulse response estimates (complex or power) over a range of delays that constitute a significant fraction of the maximal delay spread allowed by the system. The CDP or PDP for a given delay value is estimated e.g. by correlating the received data for pilot symbols with an appropriately delayed copy of the spreading sequence, a method well known in the art. The PS is often used mainly as a means to detect the existence of paths and its output resolution may be lower than that required by the RAKE.

Tuning finger (TF) 103—a device for producing a high-resolution instantaneous CDP or PDP over a narrow delay window. TF's are commonly used to locally refine the coarse PDP information provided by the PS.

Path resolving, tracking, and reporting 105—a set of signal processing and logical algorithms to extract physical path location information from the PS and TF output and to present delay estimates consistently to subsequent RAKE receiver stages. The unchanging assignment of paths to RAKE fingers is necessary to support power and interference estimation for each finger. The degree of complexity of these algorithms varies significantly depending on system parameters, ranging from simple peak detection to sophisticated deconvolution and filtering.

Scheduling and window placement 107—control logic that determines the timing of PS and TF activation and their window positions for each cycle. The timing may be fixed (periodic) or depend on signals derived from the environment, while the positioning usually depends on the location of previously detected paths.

To increase the robustness of DE under various difficult channel conditions (low signal-to-interference ratio (SIR), wide delay spread, closely-spaced paths, etc.), averaging or memory may be added to the algorithms so that the DE process operates across many channel fading cycles and is not significantly affected by the instantaneous fading realization.

Following DE, channel estimation (CE) for the reported delays is performed by turning despreaders to these delays and using the despread pilot symbols to deduce the complex path coefficient for a given delay. A variety of filtering or smoothing methods may be applied to these instantaneous estimates, in order to improve the quality of the channel estimates. These methods are well known in the art.

Regardless of the specific implementation, the complexity of the DE process is significantly higher than that of the CE operation. Similarly, the sensitivity of DE to low SIR conditions is significantly higher, causing rapid deterioration below a certain threshold, compared to the CE process which degrades more gradually.

It can be appreciated that the quality of performance of a RAKE receiver is related to how well the channel delay estimator performs. The more accurate the estimates of signal path delays, the better the RAKE receiver will perform. An exemplary channel delay estimator 200 is illustrated in FIG. 2. The channel delay estimator 200 tests differently delayed versions of the received signal for correlation with a given spreading sequence. For each hypothesized delay, the degree of correlation determines whether the hypothesized delay represents an actual delay experienced by the received signal. To carry out this process, the exemplary channel delay estimator 200 has five “probing fingers”, each associated with one of five hypothesized delays: t₀, t₁, t₂, t₃, and t₄. These could, for example, be equally spaced with respect to one another, such as at 0, Δt, 2Δt, 3Δt, and 4Δt, as illustrated in FIG. 2. As can be appreciated, there will always be some minimal amount of delay, so having t₀=0 absolutely may not be physically possible. However, the delay associated with t₀ may be used as a base offset, with each of the hypothesized delays reduced by the base offset amount, making it possible for t₀=0 relative to the base offset. By making Δt small, it is possible to fine tune a delay estimate and track changes in the delay. The choice of five probing fingers in this example is merely for illustration: The number of probing fingers in any particular embodiment is a design choice that can be less than, equal to, or greater than five.

Except for introducing a different amount of delay, each probing finger operates in the same manner. Thus, focusing now on the probing finger associated with a delay equal to zero (i.e., no delay), the received signal is supplied to a delay unit 201 that aligns the signal to be processed in accordance with the hypothesized delay (in this case, a delay of zero). The (delayed) received signal is then passed through a matched filter 203, which may be a correlator. The matched filter 203 generates an estimate of the impulse response of the channel. This estimate is generally a complex-valued signal.

If the channel parameters are subject to fast changes, the estimates, made for each of a number N of time slots, may be summed non-coherently. This means that the absolute value of the complex signal is determined (block 205), and then summed with the values obtained for the signal during other time slots (summing block 207). Alternatively, if the channel parameters are subject to slow changes, then the channel estimates may be summed coherently, so that the absolute value block 205 would not be present. In other alternative embodiments, a combination of coherent and non-coherent averaging is also possible.

In either case, the result of the summing block 207 for each position (0, Δt, 2Δt, 3Δt, and 4Δt) are compared and the position having the highest summed value is selected, as shown in FIG. 2. The real-valued summed results for each signal position of the channel delay estimator 200 are fed into a selector 210. The selector 210 determines the position having the highest summed value. The parameters associated with this position, such as the estimated delay or impulse response, may be used by the RAKE receiver. For example, in FIG. 3, the position parameters may be used by the searcher 215 to synchronize the RAKE receiver to different paths.

The fact that the channel is fading will prevent every time slot from contributing to the estimate of the delays. However, the variations of the channel in general are such that the fading process is much faster than the changes of the delays. Thus, if we assume merely for the sake of example that, on average, there are two equally strong paths with gain h₁ and h₂, two peaks will be built up over time in the cumulated sum over different time slots, so long as the delays are sufficiently well separated in time.

A problem exists, however, when the mutual difference in delay between multiple paths is small. In such cases, the accumulated sum may exhibit only one large peak that is situated somewhere between the true delays associated with two or more channel paths. As a consequence, only one path will be detected. This will detrimentally affect the performance of the RAKE receiver since, as mentioned above, the quality of performance of a RAKE receiver is related to how well the channel delay estimator performs.

As can be appreciated, taking the absolute value of the complex signal results in the loss of the phase component of the signal. Prior art related to interference cancelling requires that the tuning finger not only report the absolute values to the digital signal processor (DSP), but also give information on the complex values. The interference cancelling can, e.g., be done by subtracting a pulse shape corresponding to the transmitter and receiver filters in one path from a second path, with a gain and a phase of the pulse shape according to the largest peak, given by the calculations of the tuning fingers. Hence, the information from one path can be used for subtraction at a second path, thereby reducing the interference from the former path.

Needing the complex values, rather than the absolute values, gives rise to a more complicated hardware, and also limits the possibilities for non-coherent averaging. Furthermore, the estimates of the phase for different paths must have been made recently in order to be useful, since these vary over time. With the tuning fingers being a common resource, the requirement of having recent estimates will limit the freedom of an allocation scheme for the tuning fingers to paths with a small difference in time.

Accordingly, there is a need in the art to provide a method in a receiver to differentiate between closely-spaced transmission paths in a multipath communication system.

### SUMMARY

In a CDMA receiver, a searcher is used to synchronize the RAKE receiver to different paths in multi-path channels. Overlapping multi-path components interfere with each other and are therefore difficult to synchronize to. This invention provides a method that permits the use of more complex interference reduction methods while maintaining a simple system architecture.

For each path, a small number of correlators are used to track delays in a CDMA receiver. We refer to this collection of correlators as tuning fingers. The inventive technique could be used to improve the performance of tuning fingers. Tuning fingers try to estimate and track the different channel delays in a fading multipath channel for a CDMA system, using coherent or non-coherent averaging. The estimated delays are then used to synchronize the RAKE receiver. Using non-coherent mean values, paths with only a small difference in delay will introduce interference relative each other. This invention proposes a method to overcome this problem.

In accordance with the present invention, a method for reducing interpath interference between a first path and at least one other path in a channel delay estimator in a CDMA receiver is provided. The method includes generating an estimate of an impulse response of the first path, generating an estimate of an impulse response of the at least one other path, calculating the absolute value of the estimate of the first path, calculating the absolute value of the estimate of the at least one other path, and subtracting a pulse shape corresponding to the absolute value of the at least one other path from the absolute value of the estimate of the first path. The amplitude of the pulse shape is scaled in relation to an estimate of the phase difference between the first path and the at least one other path.

In accordance with another aspect of the invention, there is a method for reducing interpath interference between a first path signal and at least one other path signal in a radio receiver. The method includes obtaining a relative phase of the first path signal and the at least one other path signal, determining an interference component on the first path signal caused by the at least one other path signal, and removing the interference component from the first path signal.

In accordance with still another aspect of the invention, there is a channel delay estimator in a receiver comprising a plurality of correlators. A signal is applied to an input port of each of the plurality of correlators and produces a tuned output signal at a corresponding output port of the correlator. The receiver also includes a plurality of means for determining an absolute value of the tuned output signal signal. The output port of each correlator is coupled to a corresponding input of the absolute value determining means. The receiver further includes means for determining interference and an adder. The output of the interference determining means and an output of the absolute value determining means are each coupled to a respective input of the adder.

In accordance with yet another aspect of the invention, the interference determining means comprises means for obtaining a phase difference between a first signal and at least one other signal, and means for calculating an interference component on the first path signal caused by the at least one other path signal.

In accordance with still another aspect of the invention, there is a mobile radio terminal having a channel delay estimator in a receiver comprising a plurality of correlators. A signal is applied to an input port of each of the plurality of correlators and produces a tuned output signal at a corresponding output port of the correlator. The receiver also includes a plurality of means for determining an absolute value of the tuned output signal signal. The output port of each correlator is coupled to a corresponding input of the absolute value determining means. The receiver further includes means for determining interference and an adder. The output of the interference determining means and an output of the absolute value determining means are each coupled to a respective input of the adder.

It should be emphasized that the term “comprises” or “comprising,” when used in this specification, is taken to specify the presence of stated features, integers, steps, or components, but does not preclude the presence or addition of one or more other features, integers, steps, components, or groups thereof.

### BRIEF DESCRIPTION OF DRAWINGS

The objects and advantages of the invention will be understood by reading the following detailed description in conjunction with the drawings in which:

FIG. 1 is a block diagram of a typical delay estimator structure;

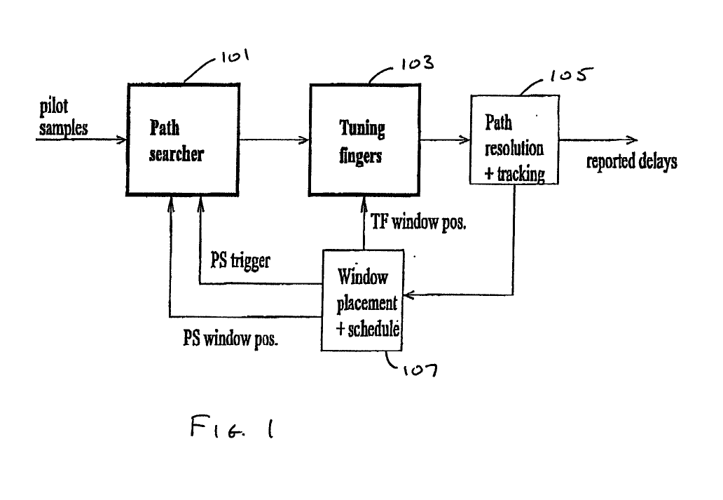

FIG. 2 is a block diagram of a conventional channel delay estimator;

FIG. 3 is a block diagram of a portion of a conventional RAKE receiver;

FIG. 4 depicts the waveforms of two rays in a multipath system;

FIG. 5 depicts a cross section of FIG. 4 at time t=d₁;

FIG. 6 is a block diagram of a portion of a channel delay estimator according to an embodiment of this invention; and

FIG. 7 is a block diagram of a typical CDMA receiver.

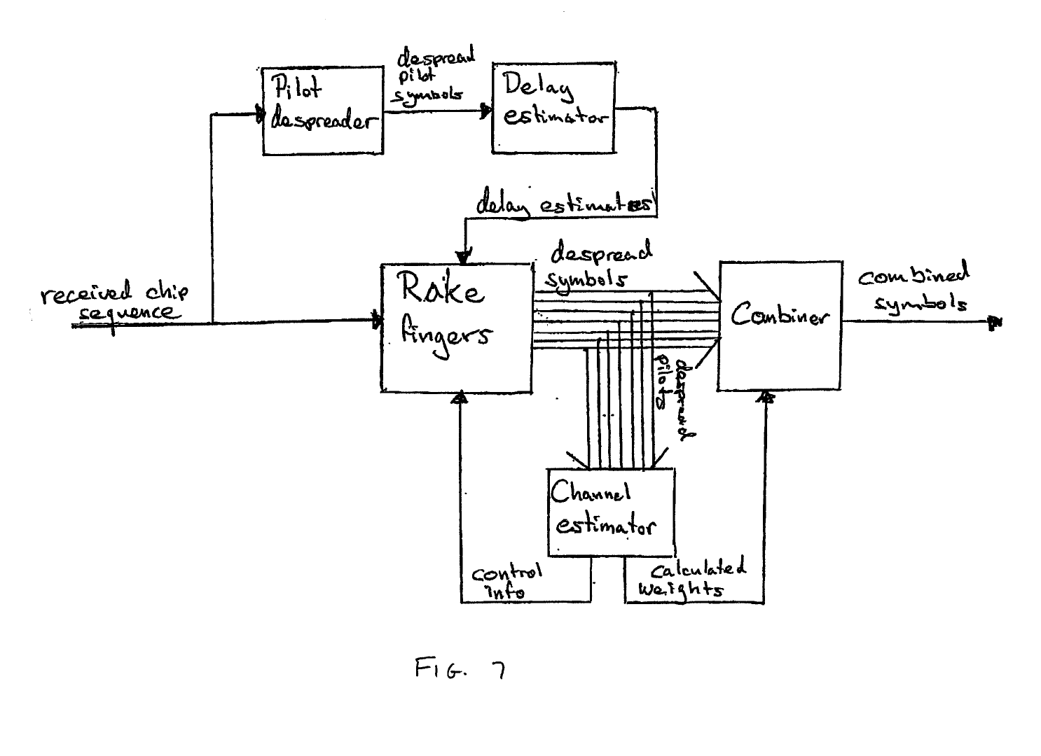

### DETAILED DESCRIPTION

The present invention involves a method and apparatus allowing for the improved cancellation of interference caused by closely-spaced rays in a multipath system.

In a multipath environment, the receiver may receive several copies of the same transmission, with each transmission having a different delay. While a RAKE receiver could use a correlator to tune to each of these signals, this may not be economically feasible. Accordingly, a RAKE receiver typically selects a finite number of rays to receive. The selection may be done with the aid of a channel delay estimator. One method used to select which rays to receive is based on signal strength. However, other criteria may be used. Once a ray is chosen, the RAKE receiver determines the delay of the component signal in order to time-align the spreading code with the signal. Thus, the relative delay of each ray is known in the RAKE receiver.

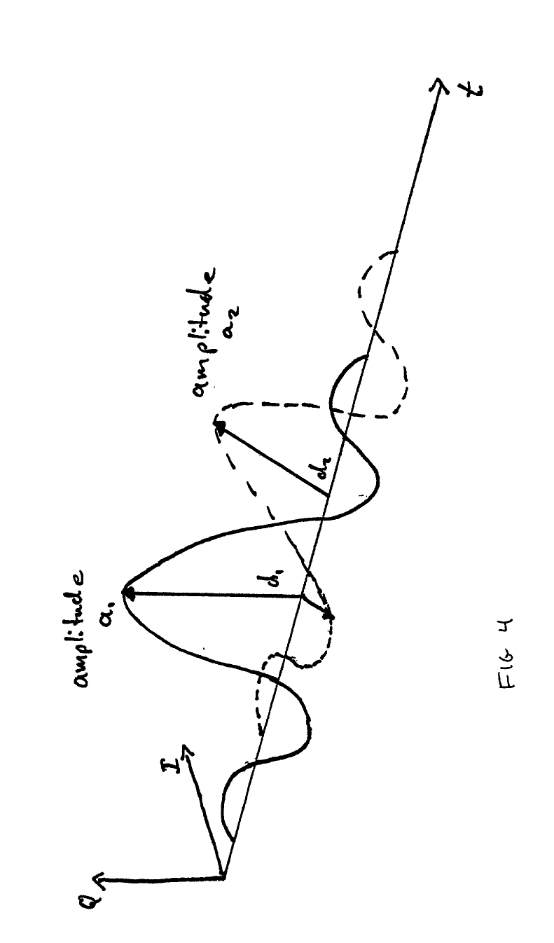

FIG. 4 depicts the waveforms of two rays in a multipath system. The waveforms are plotted in three dimensions, with the quadrature (Q), in-phase (I), and time (t) axes oriented at right angles. As shown in FIG. 4, the first ray may have an amplitude a₁ and a delay d₁. The second ray may have an amplitude a₂ and a delay d₂. Each ray may be in a plane oriented somewhere between the I and Q axes. As can be appreciated, the depicted orientation of the two rays is for purposes of illustration and not to limit the invention. Likewise, while the figures and text describe the invention is relation to two rays, this is done to simplify the explanation of the invention and not to limit the scope of the invention.

As shown in FIG. 4, the impulse response corresponding to the first ray and the impulse response corresponding to the second ray may occur at different times. However, each impulse response may overlap the other and may result in an amount of interference.

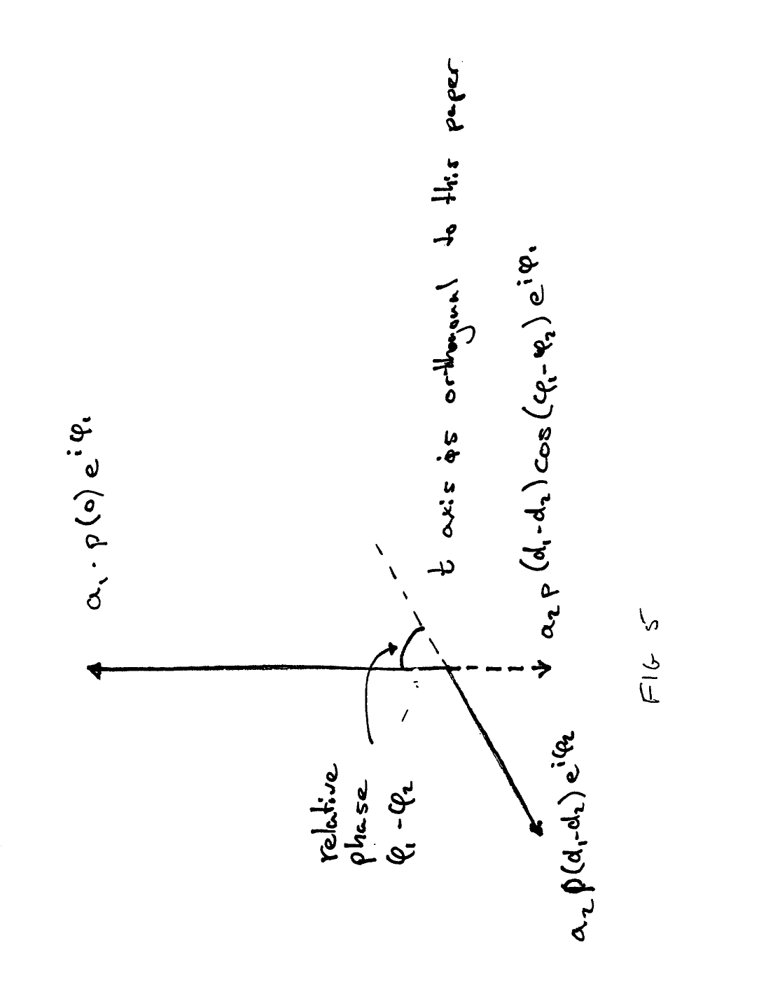

FIG. 5 shows a cross section of FIG. 4 at time t=d₁. The first ray has a relative phase of (Φ₁-Φ₂) with respect to the second ray. As shown in FIG. 5, only a portion of the second ray interferes with the first ray. The interfering portion can be calculated using Equation 1.

ε₁₂(i)=a₂·p(d₁−d₂)·cos(Φ₁−Φ₂)·e^{iΦ1} (1)

In Equation 1, ε₁₂(i) is the magnitude (or absolute value) of the interference from the second ray projected onto the first ray at a particular instant i in time and p(t) is the impulse response of the transmitter and receiver filters. The impulse response may depend upon the type of service being used. For example, while FIG. 4 shows a sync-like impulse response, the impulse response may just as easily be a root-raised cosine for a UMTS transmitter and receiver. As can be appreciated, the techniques described in this disclosure may be applied to a variety of network types, regardless of the characteristics of the filters.

Once the magnitude of the interference is determined, the interference signal may be subtracted from the first ray. As can be appreciated, an interference signal may be determined for a plurality of signals. Accordingly, the magnitude of the interference from the Nth ray projected onto the Kth ray at a particular instant i in time may be calculated using Equation 2.

ε_{KN}(i)=a_{N}·p(d_{K}−d_{N})·cos(Φ_{K}−Φ_{N})·e^{iΦK} (2)

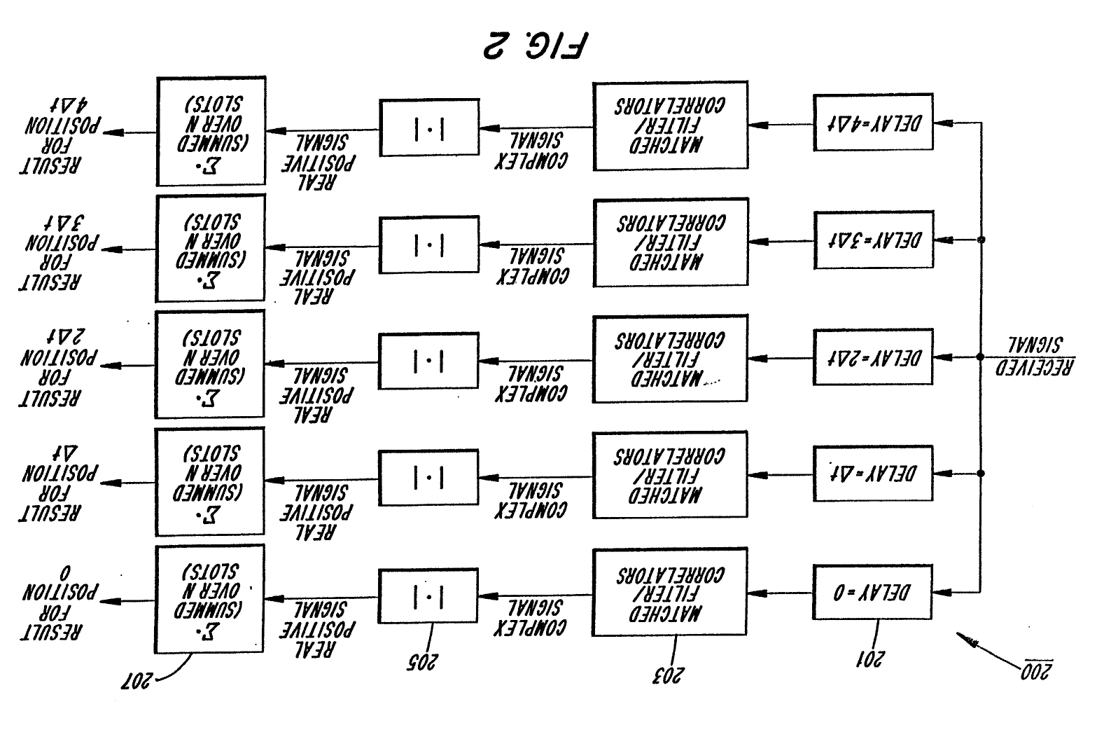

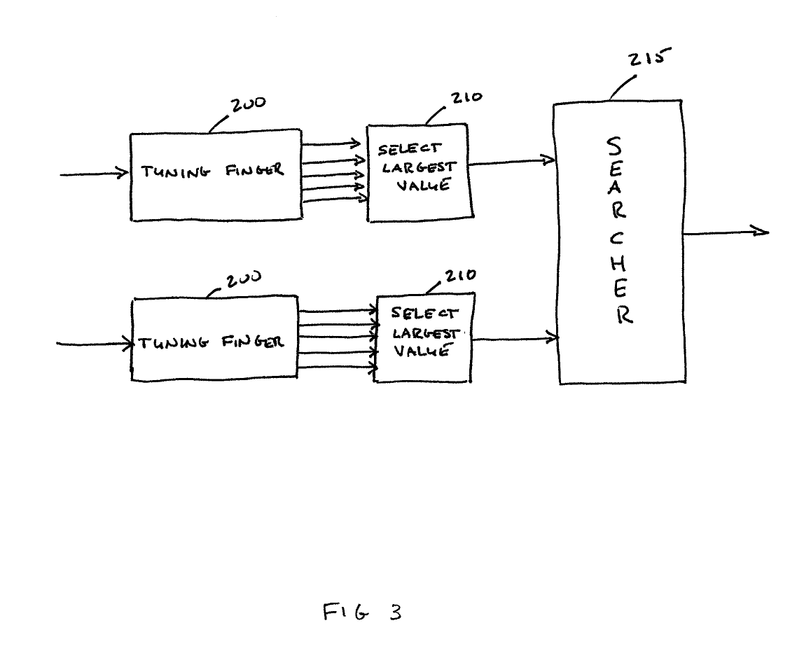

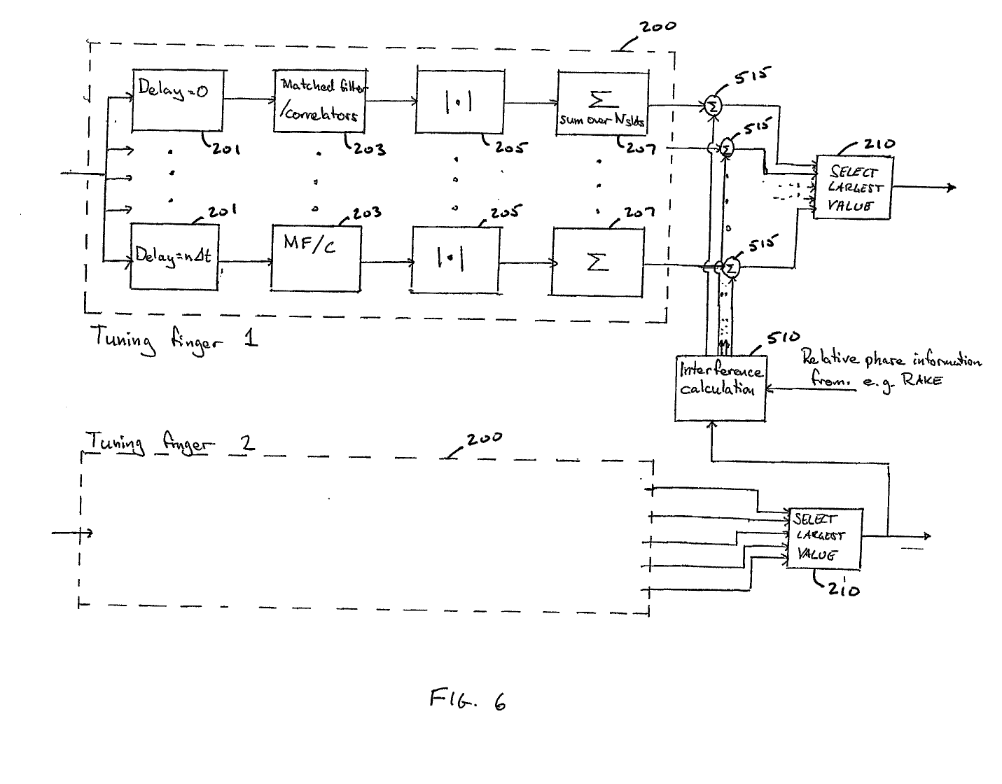

FIG. 6 is a block diagram of an arrangement to improve the performance of the channel delay estimators according to an embodiment of the invention. The operation of a conventional channel delay estimator 200 is described above with respect to FIGS. 2 and 3. As noted above, each output of the channel delay estimator 200 is a real-valued, summed result for a corresponding signal position of the channel delay estimator 200, which reflects the magnitude of an estimate of the impulse response of the channel summed over several time slots. Conventionally, the selector 210 determines the position having the highest summed value. In this embodiment, each of the outputs (channel estimates) from the channel delay estimator 200 is subtracted 515 from a corresponding output from an interference calculator 510. The result of each subtraction of the channel estimate and the corresponding interference calculation is input to the selector 210.

The interference calculator 510 calculates the magnitude of interference from one ray projected onto another ray, using, for example, the relationship in Equation 2. As shown in FIG. 6, the interference calculator 510 may use the output from a neighboring selector 210 as the interfering signal. The interference calculator 510 may get or derive the relative phase information from other portions of the receiver. For example, the estimated delay of each branch of each channel delay estimator 200 is known. The relative delay between two signals may be determined from the estimated delay, and the relative delay may be used to calculate the relative phase difference. Thus, the interference calculator 510 uses the real-valued channel estimates to determine the complex (magnitude and phase) interference from one channel on another.

In FIG. 6, the interference calculator 510 uses the strongest signal from one of the other channel delay estimators as the interfering signal. As can be appreciated, other criteria could be used to select which signal to use as the interfering signal. For example, the interfering signal could be chosen based on similarity of delay. In addition, for the sake of clarity, FIG. 6 only shows one interference calculator 510 and two channel delay estimators 200. It should be appreciated that additional interference calculators could be added to compensate for interference from additional channel delay estimators. Likewise, while FIG. 6 only shows compensating the output of the first channel delay estimator with the output of the second channel delay estimator, the output of the second channel delay estimator could be compensated using the output of the first channel delay estimator.

Having only the absolute values from the tuning fingers, the RAKE receiver may take the instantaneous phase information for the specific paths and, at each delay, subtract a pulse shape positioned relative to the other path, with a gain according to the tuning finger value at its position, and a phase which is relative phase to the difference of the two paths in the RAKE receiver. One benefit from this technique is the ability to reduce the complexity of the tuning finger, since only the absolute values are needed as output. The resolution of paths may be increased due to interference cancelling. This technique may also be used to improve the tracking of changes in path delays and improve the allocation of tuning fingers.

The invention has now been described with respect to a single embodiment. In light of this disclosure, those skilled in the art will likely make alternate embodiments of this invention. For example, the invention has been described in relation to two rays in a CDMA system. One skilled in the art would find applications for this invention in other systems prone to multipath interference. In addition, expanding the application of this invention to include more than two rays would be apparent from this disclosure. These and other alternate embodiments are intended to fall within the scope of the claims which follow.

What is claimed is:

1. A method for reducing interpath interference between a first path and at least one other path in a channel delay estimator in a radio receiver comprising the steps of:
generating an estimate of an impulse response of the first path;
generating an estimate of an impulse response of the at least one other path;
calculating the absolute value of the estimate of the first path;
calculating the absolute value of the estimate of the at least one other path; and
subtracting a pulse shape corresponding to the absolute value of the at least one other path from the absolute value of the estimate of the first path, wherein an amplitude of the pulse shape is scaled in relation to an estimate of the phase difference between the first path and the at least one other path.

2. The method of claim 1, wherein the radio receiver is a CDMA receiver.

3. A method for reducing interpath interference between a first path signal and at least one other path signal in a channel delay estimator in a radio receiver comprising the steps of:
obtaining a relative phase of the first path signal and the at least one other path signal;
determining, based on the relative phase, an interference component on the first path signal caused by the at least one other path signal; and
removing the interference component from the first path signal.

4. The method of claim 3, wherein the step of obtaining the relative phase of the first path signal and the at least one other path signal is accomplished using phase information that is available in a combiner.

5. A channel delay estimator in a receiver comprising:
a plurality of correlators, wherein a signal applied to an input port of each of the plurality of correlators produces a tuned output signal at a corresponding output port of the respective correlator;
means for determining an absolute value of the tuned output signal signal, wherein the output port of each correlator is coupled to a corresponding input of the absolute value determining means;
means for determining interference; and
an adder, wherein an output of the interference determining means and an output of the absolute value determining means are each coupled to a respective input of the adder.

6. The channel delay estimator of claim 5, wherein the interference determining means comprises:
means for obtaining a phase difference between a first signal and at least one other signal; and
means for calculating an interference component on the first path signal caused by the at least one other path signal.

7. The channel delay estimator of claim 6, wherein the calculating means comprises logic capable of evaluating the equation
ε₁₂(i)=a₂·p(d₁−d₂)·cos(Φ₁−Φ₂)·e^{iΦ1}.

8. The channel delay estimator of claim 6, wherein the means for obtaining the phase difference between the first signal and at least one other signal uses phase information available to a combiner in the receiver.

9. A mobile radio terminal having a channel delay estimator in a receiver, the channel delay estimator comprising:
a plurality of correlators, wherein a signal applied to an input port of each of the plurality of correlators produces a tuned output signal at a corresponding output port of the respective correlator;
means for determining an absolute value of the tuned output signal signal, wherein the output port of each correlator is coupled to a corresponding input of the absolute value determining means;
means for determining interference; and
an adder, wherein an output of the interference determining means and an output of the absolute value determining means are each coupled to a respective input of the adder.

10. The mobile radio terminal of claim 9, wherein the interference determining means comprises:
means for obtaining a phase difference between a first signal and at least one other signal; and
means for calculating an interference component on the first path signal caused by the at least one other path signal.

11. The mobile radio terminal of claim 10, wherein the calculating means comprises a microprocessor capable of evaluating the equation
ε₁₂(i)=a₂·p(d₁−d₂)·cos(Φ₁−Φ₂)·e^{iΦ1}.

12. The mobile radio terminal of claim 10, wherein the means for obtaining the phase difference between the first signal and at least one other signal uses phase information available to a combiner in the receiver.
